(19) United States
(12) Patent Application Publication
(10) Pub. No.: US 2026/0040547 A1
(43) Pub. Date: Feb. 5, 2026

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Kosei NODA, Yokkaichi Mie (JP)

(73) Assignee: Kioxia Corporation, Tokyo (JP)

(21) Appl. No.: 19/058,222

(22) Filed: Feb. 20, 2025

(30) Foreign Application Priority Data
Jul. 30, 2024 (JP) 2024-123228

(51) Int. Cl. H10B 43/27

(52) U.S. Cl. CPC H10B 43/27

(57) ABSTRACT

According to one embodiment, a semiconductor memory device includes a stacked body in which a plurality of conductive layers and a plurality of insulating layers are alternately stacked, a pillar penetrating the stacked body, and a contact. The stacked body has a staircase portion in which a terrace portion of the plurality of conductive layers is processed in a staircase shape. The contact penetrates the terrace portion of one conductive layer and lower conductive layers below the one conductive layer in the staircase portion. The one conductive layer is electrically connected to the contact in the terrace portion. Both surfaces of each of the plurality of conductive layers in the stacking direction including the terrace portion are covered with a first metal-containing layer. In each of the lower conductive layers, an end surface facing the contact is covered with the first metal-containing layer.

### CROSS-REFERENCE TO RELATED APPLICATION

This application is based upon and claims the benefit of priority from Japanese Patent Application No. 2024-123228, filed Jul. 30, 2024, the entire contents of which are incorporated herein by reference.

### FIELD

Embodiments described herein relate generally to a semiconductor memory device and a method for manufacturing a semiconductor memory device.

### BACKGROUND

In a semiconductor memory device, such as a three-dimensional non-volatile memory, memory cells are three-dimensionally arranged in a stacked body in which a plurality of conductive layers and a plurality of insulating layers are alternately stacked one by one. These conductive layers are processed in a staircase shape in a partial region of the stacked body, and a contact is connected to each conductive layer. The task is how to form the contact connected to each of a plurality of conductive layers that belong to different layers of the stacked body and have a height difference therebetween.

### DESCRIPTION OF THE DRAWINGS

FIGS. 1A and 1B are views illustrating an example of a schematic configuration of a semiconductor memory device according to an embodiment.

FIGS. 2A to 2E are cross-sectional views illustrating an example of a configuration of the semiconductor memory device according to the embodiment.

FIGS. 3A to 3E are cross-sectional views sequentially illustrating a portion of a procedure of a method for manufacturing the semiconductor memory device according to the embodiment.

FIGS. 4A to 4C are cross-sectional views sequentially illustrating a portion of the procedure of the method for manufacturing the semiconductor memory device according to the embodiment.

FIGS. 5A to 5C are cross-sectional views sequentially illustrating a portion of the procedure of the method for manufacturing the semiconductor memory device according to the embodiment.

FIGS. 6A to 6C are cross-sectional views sequentially illustrating a portion of the procedure of the method for manufacturing the semiconductor memory device according to the embodiment.

FIGS. 7A and 7B are cross-sectional views sequentially illustrating a portion of the procedure of the method for manufacturing the semiconductor memory device according to the embodiment.

FIGS. 8A to 8C are cross-sectional views sequentially illustrating a portion of the procedure of the method for manufacturing the semiconductor memory device according to the embodiment.

FIGS. 9A to 9C are cross-sectional views sequentially illustrating a portion of the procedure of the method for manufacturing the semiconductor memory device according to the embodiment.

FIGS. 10A to 10D are cross-sectional views sequentially illustrating a portion of the procedure of the method for manufacturing the semiconductor memory device according to the embodiment.

FIGS. 11A to 11C are cross-sectional views sequentially illustrating a portion of the procedure of the method for manufacturing the semiconductor memory device according to the embodiment.

FIGS. 12A to 12C are cross-sectional views sequentially illustrating a portion of the procedure of the method for manufacturing the semiconductor memory device according to the embodiment.

FIGS. 13A to 13C are cross-sectional views sequentially illustrating a portion of the procedure of the method for manufacturing the semiconductor memory device according to the embodiment.

FIGS. 14A to 14C are cross-sectional views illustrating a portion of a procedure of a method for forming a contact according to a modification example of the embodiment.

FIGS. 15A to 15D2 are cross-sectional views further illustrating a portion of the procedure of the method for forming the contact according to the modification example of the embodiment.

### DETAILED DESCRIPTION

Embodiments provide a semiconductor memory device and a method for manufacturing a semiconductor memory device that is capable of easily forming contacts connected to each of a plurality of conductive layers having height differences.

In general, according to one embodiment, a semiconductor memory device includes: a stacked body in which a plurality of conductive layers and a plurality of insulating layers are alternately stacked one by one and which has a staircase portion in which each of the plurality of conductive layers processed in a staircase shape is a terrace portion; a pillar that penetrates the stacked body at a position away from the staircase portion in a first direction intersecting a stacking direction of the stacked body; and a contact that penetrates the terrace portion of one conductive layer among the plurality of conductive layers and conductive layers below the one conductive layer in the staircase portion. In the terrace portion, each of the plurality of conductive layers has a smaller layer thickness than each of the plurality of conductive layers in a region in which the pillar is disposed. Both surfaces of each of the plurality of conductive layers in the stacking direction including the terrace portion are covered with a first metal-containing layer. In each of the lower conductive layers through which the contact penetrates, an end surface facing the contact is covered with the first metal-containing layer, and the one conductive layer through which the contact penetrates is electrically connected to the contact in the terrace portion.

Hereinafter, embodiments of the present disclosure will be described in detail with reference to the drawings. Further, the present disclosure is not limited by the following embodiments. In addition, elements in the following embodiments include those that may be easily assumed by those skilled in the art or those that are substantially the same.

### Example of Configuration of Semiconductor Memory Device

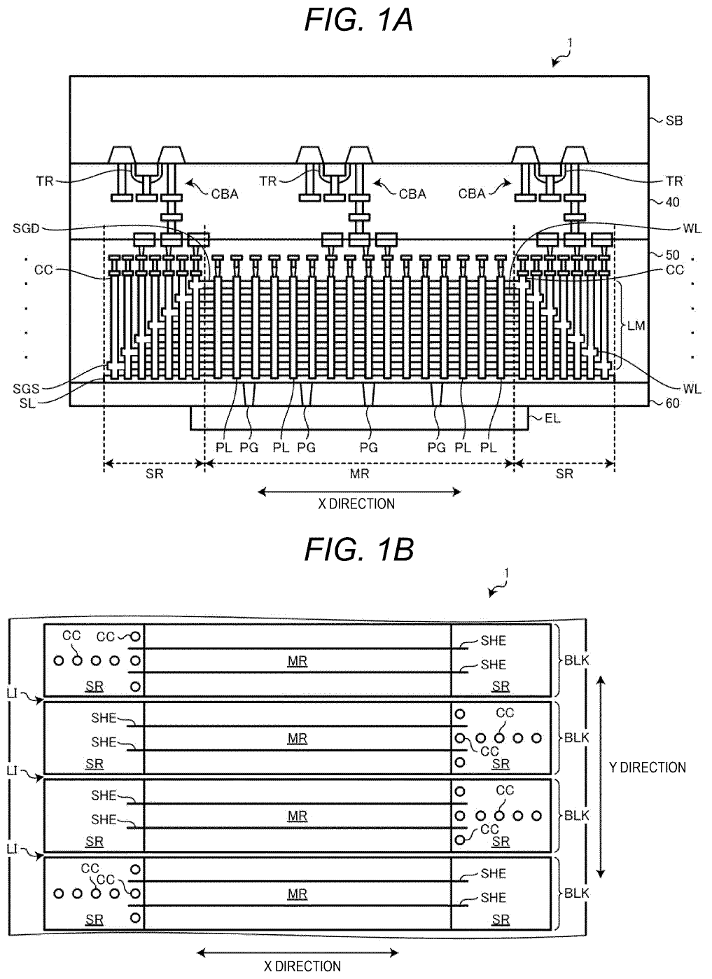

FIGS. 1A and 1B are views illustrating an example of a schematic configuration of a semiconductor memory device 1 according to the embodiment. More specifically, FIG. 1A is a cross-sectional view illustrating the semiconductor memory device 1 taken along the X direction, and FIG. 1B is a schematic plan view illustrating the layout of the semiconductor memory device 1.

However, in FIG. 1A, hatching is omitted for the sake of the clarity of the drawing. In addition, FIG. 1A illustrates configurations that are not necessarily present in the same cross section, and some upper layer wiring lines and the like are omitted.

Further, in the present specification, both the X direction and the Y direction are directions along the orientation of a surface of a word line WL, and the X direction and the Y direction are orthogonal to each other. Furthermore, an electrical drawing direction of the word line WL may be referred to as a first direction, and the first direction is a direction along the X direction. Moreover, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 1A, the semiconductor memory device 1 includes a semiconductor substrate SB on which an electrode film EL, a source line SL, one or more select gate lines SGS, a plurality of word lines WL, one or more select gate lines SGD, and a peripheral circuit CBA are provided in order from a lower side of a plane of paper.

The source line SL is disposed on the electrode film EL with an insulating layer 60 interposed therebetween. A plurality of plugs PG are disposed in the insulating layer 60, and an electrical connection between the source line SL and the electrode film EL through the plugs PG is maintained. An electrode pad for supplying power and signals to the semiconductor memory device 1 from the outside is provided in the same layer as the electrode film EL, which is not illustrated. The select gate line SGS, the plurality of word lines WL, and the select gate line SGD are stacked in this order on the source line SL. Further, FIGS. 1A and 1B illustrate a case where the electrode film EL is only one layer. However, the present disclosure is not limited thereto. A plurality of electrode films EL may be stacked with insulating layers (not illustrated) interposed therebetween.

As illustrated in FIGS. 1A and 1B, a memory region MR is disposed in a central portion of the plurality of word lines WL in the X direction, and staircase regions SR are disposed in both end portions of the plurality of word lines WL in the X direction. The memory region MR and the staircase regions SR are divided into a plurality of regions by a plurality of plate-shaped contacts LI that penetrate the plurality of word lines WL and the like and extend in the direction along the X direction.

In addition, a region that is disposed between the plate-shaped contacts LI adjacent to each other in the Y direction and includes the memory region MR and the staircase regions SR is referred to as a block region BLK. The memory region MR includes a plurality of memory cells that store data in a non-volatile manner, and the block region BLK is a unit of data erasure, which will be described below.

In addition, a plurality of separation layers SHE that penetrate the select gate line SGD and extend in the direction along the X direction are disposed between the plate-shaped contacts LI adjacent to each other in the Y direction. The plurality of separation layers SHE extend in the direction along the X direction over the entire memory region MR and reach portions of the staircase regions SR in both end portions in the X direction.

A plurality of pillars PL that penetrate the word lines WL and the select gate lines SGD and SGS in a stacking direction are disposed in the memory region MR. A lower end of the pillar PL reaches the source line SL. A plurality of memory cells are formed in intersection portions between the pillar PL and the word lines WL. Therefore, the semiconductor memory device 1 is configured as, for example, a three-dimensional non-volatile memory in which the memory cells are three-dimensionally arranged in the memory region MR.

In the staircase region SR, the plurality of word lines WL and the select gate lines SGD and SGS are processed in a staircase shape and are terminated. At this time, the plurality of word lines WL and the select gate lines SGD and SGS that constitute terrace portions move from an upper layer side to a lower layer side as they are away from the memory region MR in the X direction. Therefore, a height position of the terrace portion is lowered toward the source line SL.

In addition, the separation layer SHE extends from the memory region MR to a portion of the staircase region SR in which the select gate lines SGD are processed in a staircase shape. Therefore, in one block region BLK, the select gate line SGD is divided into a plurality of regions. In other words, the separation layer SHE penetrates portions in the layer above the plurality of word lines WL such that the upper layer portions are partitioned into patterns of the plurality of select gate lines SGD.

In the terrace portion in each step configured with the plurality of word lines WL and the select gate lines SGD and SGS, contacts CC that penetrate the word lines WL and the select gate lines SGD and SGS and are connected to the word lines WL and the select gate lines SGD and SGS in each layer in each terrace portion are disposed. In the word line WL and the select gate line SGS, one contact CC is connected to each layer. In the select gate line SGD, one contact CC is connected to each section separated by the separation layer SHE in each layer. However, a plurality of contacts CC may be connected to the word line WL in one layer, or a plurality of contacts CC may be connected to each of the sections corresponding to one layer of the select gate line SGD separated by the separation layer SHE.

Here, in one block region BLK, a plurality of contacts CC are disposed in one of the staircase regions SR on both sides in the X direction. In addition, when viewed from one side in the X direction, for example, a plurality of contacts CC are disposed for every two block regions BLK.

That is, in the example illustrated in FIG. 1B, in the block region BLK on the uppermost side of the plane of paper, a plurality of contacts CC are disposed, for example, in the staircase region SR on the left side of the plane of paper of the staircase regions SR in both end portions in the X direction. In addition, in the block regions BLK that are one block below and two blocks below the uppermost block region BLK, a plurality of contacts CC are disposed in the staircase region SR on the right side of the plane of paper of the staircase regions SR in both end portions in the X direction. Further, in the block region BLK on the lowermost side of the plane of paper, a plurality of contacts CC are disposed in the staircase region SR on the left side of the plane of paper again.

Therefore, the contacts CC in the staircase regions SR in both end portions in the X direction illustrated in FIG. 1A belong to different block regions BLK and are not actually located at the same cross section.

The word lines WL and the like which are stacked in multiple layers are individually drawn out by the contacts CC. More specifically, a write voltage, a read voltage, and the like are applied from the contacts CC to the memory cells provided in the memory region MR in the central portion of the plurality of word lines WL through the word lines WL at the same height position as the memory cells.

However, the connection form between the contact CC and the memory cell is not limited to the above. The contacts CC may be provided in the staircase regions SR on both sides of a stacked body LM in the X direction, and the memory cells may be driven from both sides of one block region BLK in the X direction.

The plurality of word lines WL and select gate lines SGD and SGS, the pillars PL, and the contacts CC are covered with an insulating layer 50. The insulating layer 50 also extends around these configurations.

The semiconductor substrate SB above the insulating layer 50 is, for example, a silicon substrate or the like. The peripheral circuit CBA including a transistor TR, a wiring line, and the like is disposed on a surface of the semiconductor substrate SB. Various voltages applied from the contacts CC to the memory cells are controlled by the peripheral circuit CBA electrically connected to the contacts CC. Therefore, the peripheral circuit CBA controls the electrical operation of the memory cells.

The peripheral circuit CBA is covered with an insulating layer 40, and the insulating layer 40 and the insulating layer 50 covering the plurality of word lines WL and the like are joined to configure the semiconductor memory device 1 including configurations, such as the plurality of word lines WL and select gate lines SGD and SGS, the pillars PL, and the contacts CC, and the peripheral circuit CBA.

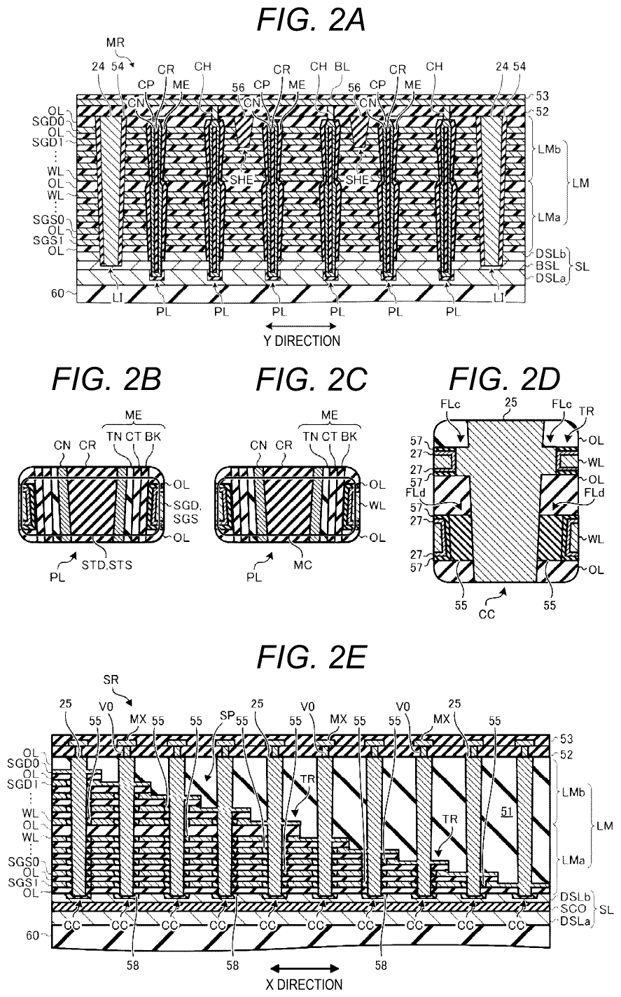

Next, an example of a detailed configuration of the semiconductor memory device 1 will be described with reference to FIGS. 2A to 2E. FIGS. 2A to 2E are cross-sectional views illustrating an example of the configuration of the semiconductor memory device 1 according to the embodiment.

More specifically, FIG. 2A is a cross-sectional view illustrating the memory region MR of the semiconductor memory device 1 taken along the Y direction. In FIG. 2A, a structure below the insulating layer 60 and a structure above an insulating layer 53, which will be described below, are omitted.

FIG. 2B is an enlarged cross-sectional view illustrating the pillar PL at the height position of the select gate line SGD or SGS. FIG. 2C is an enlarged cross-sectional view illustrating the pillar PL at the height position of the word line WL. FIG. 2D is an enlarged cross-sectional view illustrating the contact CC at the height position of the word line WL.

FIG. 2E is a cross-sectional view illustrating the staircase region SR of the semiconductor memory device 1 taken along the X direction. In FIG. 2E, the structure below the insulating layer 60 and the structure above the insulating layer 53, which will be described below, are omitted.

In addition, in the present specification, a direction that a terrace surface of the word line WL in each step in the staircase region SR faces is defined as an upward direction in the semiconductor memory device 1.

As illustrated in FIG. 2A, the source line SL has a multilayer structure in which, for example, a lower source line DSLa, an intermediate source line BSL, and an upper source line DSLb are stacked in this order on the insulating layer 60. In addition, the intermediate source line BSL is disposed below the stacked body LM in the memory region MR.

The lower source line DSLa, the intermediate source line BSL, and the upper source line DSLb are, for example, polysilicon layers or the like. Among them, at least the intermediate source line BSL may be a conductive polysilicon layer or the like in which impurities are diffused.

Further, the source line SL is connected to the peripheral circuit CBA through the electrode film EL by a through contact (not illustrated) that penetrates the insulating layer 50 outside the stacked body LM and extends from the electrode film EL to the peripheral circuit CBA.

The stacked body LM is disposed on the source line SL. The stacked body LM includes stacked bodies LMa and LMb in which a plurality of word lines WL and a plurality of insulating layers OL are alternately stacked one by one.

The stacked body LMa is disposed on the source line SL. A plurality of select gate lines SGS0 and SGS1 are disposed below the word line WL in the lowermost layer of the stacked body LMa in this order from the upper layer side of the stacked body LMa, with the insulating layer OL interposed therebetween. The stacked body LMb is disposed on the stacked body LMa. A plurality of select gate lines SGD0 and SGD1 are disposed above the word line WL in the uppermost layer of the stacked body LMb in this order from the upper layer side of the stacked body LMb, with the insulating layer OL interposed therebetween.

However, the number of layers of the word lines WL and the select gate lines SGD and SGS stacked in the stacked body LM is freely selected. The word line WL and the select gate lines SGD and SGS are, for example, tungsten layers, molybdenum layers, or the like. The insulating layer OL is, for example, a silicon oxide layer or the like.

In addition, as an example, the thickness of each of the word line WL and the select gate lines SGD and SGS is settable to, for example, 15 nm or more and 30 nm or less. Further, the thickness of the insulating layer OL may be equal to the thickness of the word line WL and the select gate lines SGD and SGS.

As illustrated in FIG. 2B to FIG. 2D, a metal-containing layer 27 and a metal-containing layer 57 are disposed in this order on both surfaces of the plurality of word lines WL and select gate lines SGD and SGS in the stacking direction.

When the word line WL or the like is a tungsten layer or the like, the metal-containing layer 27 is at least any of a titanium layer, a titanium nitride layer, a tantalum layer, and a tantalum nitride layer and functions as a barrier metal layer that prevents diffusion of tungsten atoms into a configuration in the vicinity of the word line WL. When the word line WL or the like is a molybdenum layer or the like, the metal-containing layer 27 is, for example, a molybdenum nitride layer or the like and functions as a precursor for forming the word line WL or the like. The metal-containing layer 57 is, for example, a metal oxide layer and is specifically an aluminum oxide (Al₂O₃) layer, a hafnium oxide (HfOx) layer, a zirconium oxide (ZrOx) layer, or the like. In addition, at least two types of layers among these layers may be stacked and used as the metal-containing layer 57.

Further, as an example, when the thickness of each of the word line WL and the select gate lines SGD and SGS is, for example, 15 nm or more and 30 nm or less, the thickness of each of the metal-containing layers 27 and 57 is settable to, for example, 1 nm or more and 5 nm or less.

As illustrated in FIG. 2A, the upper surface of the stacked body LM is covered with an insulating layer 52. The insulating layer 52 is covered with the insulating layer 53. Each of the insulating layers 52 and 53 and an insulating layer 51 which will be described below constitute a portion of the insulating layer 50 illustrated in FIGS. 1A and 1B.

As described above, the stacked body LM is divided in the Y direction by the plurality of plate-shaped contacts LI. That is, the plate-shaped contacts LI are arranged in the Y direction and extend in the stacking direction of the stacked body LM and the direction along the X direction.

As described above, the plate-shaped contact LI continuously extends from one end portion to the other end portion of the stacked body LM in the X direction in the stacked body LM. In addition, the plate-shaped contact LI penetrates the stacked body LM and the upper source line DSLb and reaches the intermediate source line BSL in the memory region MR.

Further, the plate-shaped contact LI has, for example, a tapered shape in which the width in the Y direction is reduced from an upper end portion toward a lower end portion. Alternatively, the plate-shaped contact LI has, for example, a bowing shape in which the width in the Y direction is the maximum value at a predetermined position between the upper end portion and the lower end portion.

Each of the plate-shaped contacts LI includes an insulating layer 54 and a conductive layer 24. The insulating layer 54 is, for example, a silicon oxide layer or the like. The conductive layer 24 is, for example, a tungsten layer, a conductive polysilicon layer, or the like.

The insulating layer 54 covers a side wall of the plate-shaped contact LI that faces the Y direction. A space inside the insulating layer 54 covering the side wall of the plate-shaped contact LI is filled with the conductive layer 24, and the conductive layer 24 is electrically connected to the source line SL including the intermediate source line BSL.

However, instead of the plate-shaped contact LI, a plate-shaped member which is filled with an insulating layer may penetrate the stacked body LM and extend in the direction along the X direction to divide the stacked body LM in the Y direction.

A plurality of separation layers SHE that penetrate the upper layer portion of the stacked body LMb and extend in the direction along the X direction are disposed between the plate-shaped contacts LI adjacent to each other in the Y direction. The separation layer SHE is an insulating layer 56, such as a silicon oxide layer, that penetrates the select gate lines SGD0 and SGD1 and reaches the insulating layer OL immediately below the select gate line SGD1.

In other words, these separation layers SHE penetrating the upper layer portion of the stacked body LMb extend through the memory region MR and a portion of the staircase region SR in the X direction between the plate-shaped contacts LI to partition the upper layer portion of the stacked body LMb into the select gate lines SGD0 and SGD1.

A plurality of pillars PL that penetrate the stacked body LM, the upper source line DSLb, and the intermediate source line BSL and reach the lower source line DSLa are dispersively disposed in the memory region MR.

The plurality of pillars PL are arranged, for example, in zigzag when viewed from the stacking direction of the stacked body LM. Each of the pillars PL has, for example, a circular shape, an elliptical shape, or an oval shape as a cross-sectional shape in a direction along the stacking direction of the stacked body LM, that is, in a direction along the XY plane.

In addition, in the pillar PL, each of a portion that penetrates the stacked body LMa and a portion that penetrates the stacked body LMb has a tapered shape in which the diameter and the cross-sectional area are reduced from the upper layer side toward the lower layer side. Alternatively, in the pillar PL, each of the portion that penetrates the stacked body LMa and the portion that penetrates the stacked body LMb has a bowing shape in which the diameter and the cross-sectional area are the maximum values at a predetermined position between the upper layer side and the lower layer side.

Each of the plurality of pillars PL has a memory layer ME that extends in the stacking direction in the stacked body LM, a channel layer CN that penetrates the stacked body LM and is connected to the intermediate source line BSL, a cap layer CP that covers an upper surface of the channel layer CN, and a core layer CR that is a core material of the pillar PL.

As illustrated in FIGS. 2B and 2C, the memory layer ME has a multilayer structure in which a block insulating layer BK, a charge storage layer CT, and a tunnel insulating layer TN are stacked in this order from an outer peripheral side of the pillar PL. More specifically, the memory layer ME is disposed on a side surface of the pillar PL excluding a depth position of the intermediate source line BSL. In addition, the memory layer ME is also disposed on a bottom surface of the pillar PL that reaches the depth of the lower source line DSLa.

The channel layer CN penetrates the stacked body LM, the upper source line DSLb, and the intermediate source line BSL and reaches the depth of the lower source line DSLa inside the memory layer ME. More specifically, the channel layer CN is disposed on the side surface and the bottom surface of the pillar PL, with the memory layer ME interposed therebetween. Meanwhile, a portion of the side surface of the channel layer CN is in contact with the intermediate source line BSL. Therefore, the channel layer CN is electrically connected to the source line SL including the intermediate source line BSL. A space inside the channel layer CN is filled with the core layer CR.

In addition, each of the plurality of pillars PL has the cap layer CP in an upper end portion. The cap layer CP is disposed in the upper end portion of the pillar PL to cover at least the upper end portion of the channel layer CN and is connected to the channel layer CN. In addition, the cap layer CP is connected to a bit line BL disposed in the insulating layer 53 through a plug CH disposed in the insulating layer 52. The bit line BL extends above the stacked body LM in the direction along the Y direction to intersect the drawing direction of the word line WL.

Further, in FIG. 2A, the plugs CH are connected only to three pillars PL that penetrate three separated select gate lines SGD, respectively, among six pillars PL and are electrically connected to the bit line BL illustrated in FIG. 2A. The rest of the pillars PL are connected to another bit line BL that extends parallel to the bit line BL illustrated in FIG. 2A in the direction along the Y direction at a position different from that in the cross section illustrated in FIG. 2A through the plugs CH (not illustrated in FIG. 2A).

The block insulating layer BK and the tunnel insulating layer TN of the memory layer ME and the core layer CR are, for example, silicon oxide layers or the like. The charge storage layer CT of the memory layer ME is, for example, a silicon nitride layer or the like. The channel layer CN and the cap layer CP are, for example, semiconductor layers such as polysilicon layers or amorphous silicon layers.

As illustrated in FIG. 2C, each memory cell MC is formed in a portion in which the side surface of the pillar PL faces each word line WL by the above-described configuration. A predetermined voltage is applied from the word line WL to write and read data to and from the memory cell MC.

In addition, as illustrated in FIG. 2B, select gates STD are formed in portions in which the side surface of the pillar PL faces the select gate lines SGD0 and SGD1 in the layers above the word line WL, respectively. Further, select gates STS are formed in portions in which the side surface of the pillar PL faces the select gate lines SGS0 and SGS1 in the layers below the word line WL, respectively.

A predetermined voltage is applied from each of the select gate lines SGD and SGS to turn on or off the select gates STD and STS such that the memory cells MC of the pillar PL, to which the select gates STD and STS belong, are changeable to a selected state or an unselected state.

As illustrated in FIG. 2E, the staircase region SR has a staircase portion SP in which a plurality of word lines WL and select gate lines SGD and SGS are processed in a staircase shape. The staircase portion SP illustrated in FIG. 2E is a portion, in which the contacts CC are disposed and which has a function of drawing out the word lines WL and the like, in the staircase region SR divided into the plurality of block regions BLK.

The staircase portion SP is covered with the insulating layer 51. The insulating layer 51 reaches, for example, a height position of the uppermost layer of the stacked body LM, and the insulating layers 52 and 53 also cover an upper surface of the insulating layer 51. As described above, the insulating layer 51 also constitutes a portion of the insulating layer 50 illustrated in FIGS. 1A and 1B.

In addition, in the staircase region SR, the source line SL includes an intermediate insulating layer SCO interposed between the upper source line DSLb and the lower source line DSLa instead of the intermediate source line BSL. The intermediate insulating layer SCO is, for example, a silicon oxide layer or the like.

Therefore, the plate-shaped contact LI penetrates the insulating layer 51, the stacked body LM, and the upper source line DSLb and reaches the intermediate insulating layer SCO in the staircase region SR.

In the staircase portion SP, the plurality of word lines WL and select gate lines SGD and SGS are processed in a staircase shape and have terrace portions TR with no overlapping upper layer portions in the stacking direction of the stacked body LM. A layer thickness of the terrace portion TR is smaller than a layer thickness of portions other than the word lines WL and the select gate lines SGD and SGS, that is, portions that overlap each other in the stacking direction of the stacked body LM. More specifically, the layer thickness of the terrace portion TR is, for example, equal to or less than half of the layer thickness of the other portions.

For example, when the thickness of each of the word lines WL and the select gate lines SGD and SGS is, for example, 15 nm or more and 30 nm or less, the thickness of each of the terrace portions TR is settable to, for example, 5 nm or more and 20 nm or less.

In addition, a plurality of contacts CC that are connected to the individual word lines WL and the like processed in the staircase shape are disposed in the staircase portion SP. The contact CC is connected to an upper layer wiring line MX disposed in the insulating layer 53 through a plug V0 disposed in the insulating layer 52. The upper layer wiring line MX is electrically connected to the peripheral circuit CBA (see FIGS. 1A and 1B).

Therefore, it is possible to electrically draw out the word line WL in each layer and the select gate lines SGD and SGS in the layers above and below the word line WL from one end side or the other end side of the stacked body LM in the X direction. That is, with the above configuration, a predetermined voltage is applied from the peripheral circuit CBA to the memory cell MC through the upper layer wiring line MX, the contact CC, the word line WL, and the like to operate the memory cell MC as a storage element.

In addition, in the example illustrated in FIG. 2E, in the staircase portion SP, the word line WL and the insulating layer OL form a pair, and the word line WL rises and falls in the X direction by one layer at a time. However, in one block region BLK, the staircase portion SP may be configured such that the word line WL also rises and falls in the Y direction. In this case, the staircase portion SP is provided with a plurality of rows of staircase structures which are arranged in the Y direction and each of which extends in the X direction. This staircase structure is also referred to as a multi-row staircase.

In the multi-row staircase, in one row extending in the X direction, the word line WL rises and falls in the X direction by a plurality of layers at a time. That is, in the case of a two-row staircase having two rows of staircase structures, in one row, the word line WL rises and falls in the X direction by two layers at a time. In the case of a three-row staircase, in one row, the word line WL rises and falls in the X direction by three layers at a time.

In other words, the plurality of word lines WL provided in the stacked body LM constitute any terrace portions TR in the multi-row staircase, and the contacts CC are connected to the terrace portions TR to electrically draw out the plurality of word lines WL provided in the stacked body LM.

Each contact CC in the staircase portion SP penetrates the insulating layer 51, the word line WL and the select gate line SGD or SGS constituting the terrace portion TR, and a portion of the stacked body LM in the layer below them and reaches the source line SL, at a position that overlaps the terrace portion TR of each of the plurality of word lines WL and the select gate lines SGD and SGS constituting each step of the staircase portion SP in the stacking direction. Further, in the example illustrated in FIG. 2E, a plurality of contacts CC reach the upper source line DSLb in the source line SL. However, the contacts CC may reach the lower source line DSLa.

Each contact CC is electrically connected to the word line WL or the select gate line SGD or SGS in the uppermost layer that constitutes the terrace portion TR in the portion of the stacked body LM through which the contact CC penetrates. An insulating layer 55 or the like is disposed between the contact CC and the word lines WL and the select gate lines SGD and SGS in the layers below the word line WL or the select gate line SGD or SGS to which each contact CC is to be connected, and the lower end portion of the contact CC that reaches the upper source line DSLb is covered with an insulating layer 58. Therefore, the contact CC is electrically insulated from the word lines WL and the select gate lines SGD and SGS in the lower layers and the source line SL.

A detailed configuration of the contact CC and the word line WL or the like to which the contact CC is to be connected is illustrated in FIG. 2D. In FIG. 2D, the contact CC to be connected to any word line WL will be described.

As illustrated in FIG. 2D, a flange portion FLc that protrudes toward the word line WL to which the contact CC is to be connected is disposed on the side wall of the contact CC at the height position of the word line WL to which the contact CC is to be connected and which constitutes the terrace portion TR. In addition, a plurality of flange portions FLd that protrude toward the word lines WL and the like in the layers below the word line WL to which the contact CC is to be connected are disposed on the side wall of the contact CC at the height positions of the lower word lines WL or the like.

The flange portion FLc is configured integrally with a main body portion of the contact CC that extends while penetrating the stacked body LM and includes a conductive layer 25 similarly to the main body portion of the contact CC. It is preferable that the conductive layer 25 is made of the same material as the word line WL or the like such as a tungsten layer or a molybdenum layer. However, the conductive layer 25 and the word line WL or the like may be made of different metal materials. For example, the conductive layer 25 is a tungsten layer, and the word line WL or the like is a molybdenum layer. A layer thickness of the flange portion FLc is substantially equal to the total layer thickness of the word line WL in the terrace portion TR of the word line WL to which the contact CC is to be connected and the metal-containing layers 27 and 57 on both surfaces of the word line WL.

Meanwhile, each of the plurality of flange portions FLd includes the insulating layer 55 such as a silicon oxide layer. A layer thickness of the flange portion FLd is substantially equal to the total layer thickness of the word line WL or the like at the height position corresponding to the flange portion FLd and the metal-containing layers 27 and 57 on both surfaces of the word line WL or the like.

Here, that the layer thickness of the flange portion FLc is substantially equal to the layer thickness of the word line WL and the metal-containing layers 27 and 57 in the terrace portion TR and that the layer thickness of the flange portion FLd is substantially equal to the layer thickness of the word line WL and the metal-containing layers 27 and 57 corresponding to the flange portion FLd mean that the layer thicknesses are substantially equal to each other to an extent that a difference that may be caused by a manufacturing error in a manufacturing process, which will be described below, is allowed, in addition to a case where the layer thicknesses are completely equal to each other.

In addition, at least the flange portion FLd that is adjacent to the flange portion FLc in the stacking direction among the flange portions FLd has a larger protrusion distance from the side wall of the main body portion of the contact CC than the flange portion FLc. Alternatively, any of the plurality of flange portions FLd may have a larger protrusion distance than the flange portion FLc.

For example, when the thickness of each of the word line WL and the select gate lines SGD and SGS is, for example, 15 nm or more and 30 nm or less, the protrusion distance of each of the plurality of flange portions FLd is settable to, for example, 15 nm or more and 150 nm or less, and the protrusion distance of the flange portion FLc is settable to less than the protrusion distance of the flange portions FLd.

As described above, at least the flange portion FLd adjacent to the flange portion FLc in the stacking direction has a larger protrusion distance than the flange portion FLc. Therefore, in the word line WL to which the contact CC is to be connected and the word line WL which is adjacent to the word line WL, to which the contact CC is to be connected, in the stacking direction with the insulating layer OL interposed therebetween, the surfaces facing each other are covered with the insulating metal-containing layer 57, and a leakage current between these word lines WL is reduced. In addition, the flange portion FLc of the contact CC that is not covered with the metal-containing layer 57 and the like does not have a portion overlapping the word line WL adjacent in the stacking direction in the height direction and faces the insulating layer 55 with the insulating layer OL interposed therebetween. Therefore, the leakage current between the word lines WL is also reduced.

In addition, the main body portion of each contact CC has, for example, a tapered shape in which the diameter and the cross-sectional area are reduced from an upper end portion toward a lower end portion. Alternatively, the main body portion of the contact CC has, for example, a bowing shape in which the diameter and the cross-sectional area have the maximum values at a predetermined position between the upper end portion and the lower end portion.

In addition, the metal-containing layer 27 and the metal-containing layer 57 cover in this order an end surface, which faces the flange portion FLd of the contact CC, in the word line WL or the like in the layer below the word line to which the contact CC is to be connected. As described above, the insulating layer 55 and the metal-containing layer 57, which is a metal oxide layer or the like, are interposed between the main body portion of the contact CC and the lower word line WL. Therefore, the electrically insulating state of the contact CC from the lower word line WL or the like is maintained.

On the other hand, in the word line WL to which the contact CC is to be connected, at least the end surface facing the flange portion FLc of the contact CC is not covered with the metal-containing layer 57. As described above, the metal-containing layer 57, which is a metal oxide layer or the like, is not interposed between the main body portion of the contact CC and the word line WL to which the contact CC is to be connected. Therefore, the contact CC is electrically connected to the word line WL to which the contact CC is to be connected.

In addition, the metal-containing layer 27, which is a conductor, may cover the end surface, which faces the flange portion FLc, in the word line WL to which the contact CC is to be connected, as illustrated in FIG. 2D, or may not cover the end surface, which faces the flange portion FLc, in the word line WL to which the contact CC is to be connected, regardless of the example illustrated in FIG. 2D.

The contact CC that is to be connected to any word line WL has been described above. However, the contact CC that is to be connected to the select gate line SGD or SGS also has the same configuration as described above.

That is, the contact CC includes a flange portion FLc which is the conductive layer 25 or the like and is configured integrally with the main body portion of the contact CC at the height position of the select gate line SGD or the select gate line SGS to which the contact CC is to be connected and a plurality of flange portions FLd having the insulating layer 55 at the height position of the word line WL or the like in the layer below the select gate line SGD or the select gate line SGS. The flange portion FLc is thinner than the flange portion FLd and has a smaller protrusion distance than the flange portion FLd as in the terrace portion TR of the select gate line SGD or SGS.

In addition, at least the metal-containing layer 57 is not interposed between the select gate line SGD or the select gate line SGS to which the contact CC is to be connected and the end surface of the flange portion FLc facing the select gate line SGD or the select gate line SGS. On the other hand, the metal-containing layers 27 and 57 are interposed between the word line WL or the like in the layer below the select gate line SGD or the select gate line SGS and the end surface of the flange portion FLd facing the word line WL or the like in this order from the word line WL or the like.

As illustrated in FIGS. 2B and 2C, the metal-containing layers 27 and 57 that cover the word line WL or the like also have the same layer structure as the word line WL or the like to which the contact CC is not to be connected around the pillar PL. That is, the metal-containing layer 27 and the metal-containing layer 57 also cover in this order the end surface of the word line WL or the like which faces the pillar PL. Therefore, the metal-containing layer 57 functions as a metal block layer of the memory cell MC formed in the pillar PL.

### Method for Manufacturing Semiconductor Memory Device

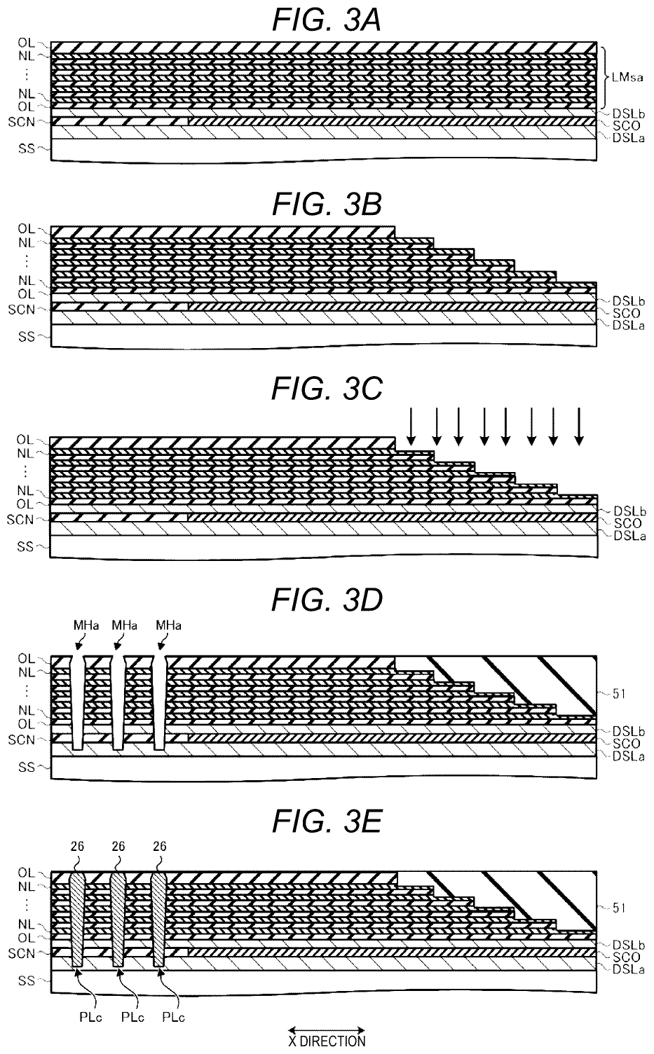

Next, a method for manufacturing the semiconductor memory device 1 according to the embodiment will be described with reference to FIGS. 3A to 13C. FIGS. 3A to 13C are views sequentially illustrating a portion of a procedure of the method for manufacturing the semiconductor memory device 1 according to the embodiment.

First, FIGS. 3A to 3E illustrate a stacked body LMsa which is a lower layer portion of the stacked body LM before the word lines WL are formed and an aspect in which various configurations are formed in the stacked body LMsa. FIGS. 3A to 3E are cross-sectional views illustrating a region that will be the memory region MR and the staircase region SR later taken along the X direction.

As illustrated in FIG. 3A, the lower source line DSLa, an intermediate sacrificial layer SCN or the intermediate insulating layer SCO, and the upper source line DSLb are formed in this order on a supporting substrate SS.

A semiconductor substrate, such as a silicon substrate, an insulating substrate, such as a ceramic substrate, a conductive substrate, or the like may be used as the supporting substrate SS. The insulating layer 60 (see FIGS. 2A to 2E and the like) described above may be formed on an upper surface of the supporting substrate SS.

The intermediate sacrificial layer SCN is formed in a region on the supporting substrate SS that will be the memory region MR later, and the intermediate insulating layer SCO is formed in a region on the supporting substrate SS that will be the staircase region SR later. The intermediate sacrificial layer SCN is, for example, a silicon nitride layer or the like and is a layer that will be replaced later with a polysilicon layer or the like to become the intermediate source line BSL. The intermediate insulating layer SCO is, for example, a silicon oxide layer or the like as described above.

In addition, the stacked body LMsa in which a plurality of insulating layers NL and a plurality of insulating layers OL are alternately stacked one by one is formed on the upper source line DSLb. The insulating layer NL is, for example, a silicon nitride layer or the like and functions as a sacrificial layer that will be replaced later with a conductive material to become the word line WL or the select gate line SGS.

As illustrated in FIG. 3B, the insulating layer NL and the insulating layer OL are processed in a staircase shape in a partial region of the stacked body LMsa. This process is capable of being performed by repeating slimming of a mask pattern of a photoresist layer and etching of the insulating layer NL and the insulating layer OL in the stacked body LMsa a plurality of times.

That is, the mask pattern is formed on an upper surface of the stacked body LMsa, and, for example, the insulating layer NL and the insulating layer OL of an exposed portion are etched and removed one by one. In addition, an end portion of the mask pattern is retreated by processing with oxygen plasma or the like to newly expose the upper surface of the stacked body LMsa, and the insulating layer NL and the insulating layer OL are further etched and removed one by one. This process is repeated a plurality of times to form the above-described staircase shape.

Further, instead of the above-described method of processing the insulating layers NL and OL from the uppermost layer to the lowermost layer of the stacked body LMsa into the staircase shape in order, a staircase shape corresponding to a plurality of layers may be collectively processed.

In this case, a plurality of strip-shaped mask patterns that are arranged apart from each other in the X direction and extend in the Y direction are formed in a region that becomes the staircase portion SP, and the slimming of the plurality of mask patterns and the etching of the insulating layers NL and OL are repeated a plurality of times to process the insulating layers NL and OL on the upper layer side of the stacked body LMsa into a staircase shape. Therefore, a plurality of staircase shapes having the plurality of mask patterns as vertices are formed. In addition, after the staircase shape close to the region that will become the memory region MR later is protected, the staircase shape on the side away from the region that will become the memory region MR later is dug down until the lowermost step reaches the insulating layers NL and OL in the lowermost layer. Therefore, it is possible to collectively form a staircase shape corresponding to a plurality of layers.

In addition, even when the multi-row staircase is formed, it is possible to use a method of sequentially processing the layers of the stacked body LMsa from the uppermost layer to the lowermost layer in a staircase shape or a method of collectively forming the layers of the stacked body LMsa. When the multi-row staircase is formed, first, the sacrificial layer NL is processed to rise and fall in the Y direction by one layer at a time, thereby providing a plurality of rows of steps in the Y direction. Then, for example, the plurality of rows are processed in a staircase shape by any of the above-described methods to obtain a multi-row staircase.

As illustrated in FIG. 3C, the terrace portions of a plurality of sacrificial layers NL processed in the staircase shape are processed by, for example, reactive ion etching (RIE) or the like to reduce the layer thickness of the sacrificial layer NL of each terrace portion. At this time, it is preferable to process the terrace portion such that the layer thickness of the terrace portion is equal to or less than half of the original layer thickness of the sacrificial layer NL. Further, in portions other than the terrace portions, since the sacrificial layers NL overlap each other in the stacking direction, the original layer thickness is maintained.

As illustrated in FIG. 3D, the insulating layer 51 that covers the staircase portion and reaches the height of the upper surface of the stacked body LMsa is formed. The insulating layer 51 is also formed in an outer region of the stacked body LMsa.

In addition, a plurality of memory holes MHa that extend through the stacked body LMsa in the stacking direction are formed. The memory hole MHa is a portion that will be a lower structure of the pillar PL later. The plurality of memory holes MHa are disposed in a region that will be the memory region MR later, penetrate the stacked body LMsa, the upper source line DSLb, and the intermediate sacrificial layer SCN, and reach the lower source line DSLa.

As illustrated in FIG. 3E, the memory holes MHa are filled with a sacrificial layer 26 such as an amorphous silicon layer or a CVD-carbon layer. Therefore, pillars PLC obtained by filling the plurality of the memory holes MHa with the sacrificial layers 26 are formed in the region that will be the memory region MR later.

In addition, the processes illustrated in FIGS. 3A to 3E are interchangeable in order. For example, the formation of the staircase shape in the stacked body LMsa illustrated in FIGS. 3B and 3C may be performed after the formation of the pillars PLc illustrated in FIGS. 3D and 3E.

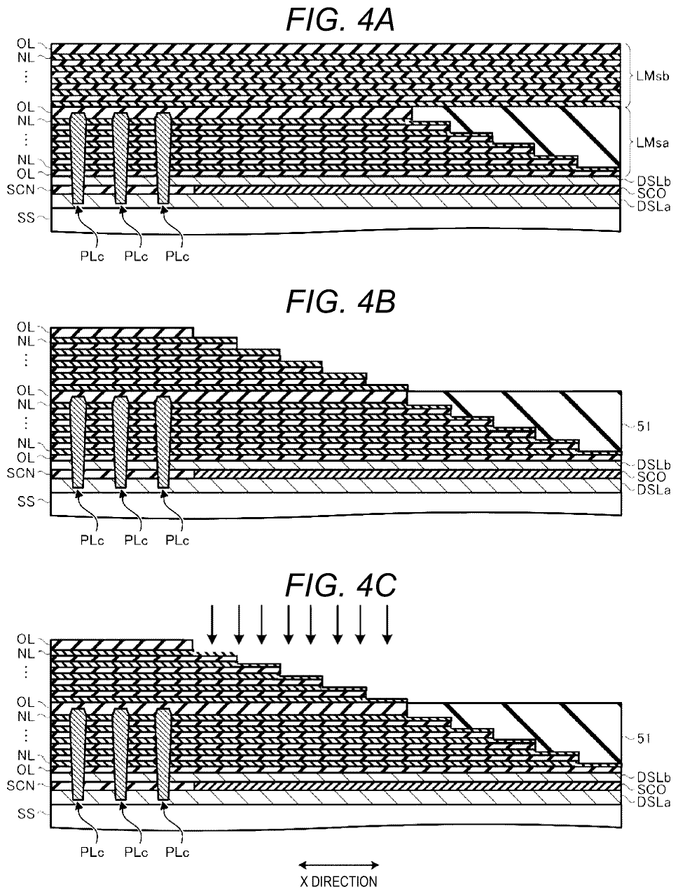

Next, FIGS. 4A to 7B illustrate an aspect in which a stacked body LMsb, which is an upper layer portion of the stacked body LM before the word lines WL are formed, is formed and various configurations are formed in the stacked body LMsb. FIGS. 4A to 4C, FIGS. 5A to 5C, and FIGS. 7A and 7B are cross-sectional views illustrating regions that will be the memory region MR and the staircase region SR later taken along the X direction, as in FIGS. 3A to 3E.

As illustrated in FIG. 4A, the stacked body LMsb which covers the stacked body LMsa including the portion processed in the staircase shape and in which a plurality of insulating layers NL and a plurality of insulating layers OL are alternately stacked one by one is formed. The sacrificial layer NL of the stacked body LMsb will be replaced with a conductive layer later to become the word line WL or the select gate line SGD.

As illustrated in FIG. 4B, the insulating layers NL and the insulating layers OL are processed in a staircase shape in a partial region of the stacked body LMsb. This process is capable of being performed by repeating a plurality of times the slimming of the mask pattern of the photoresist layer or the like and the etching of the insulating layers NL and the insulating layers OL of the stacked body LMsb, as in the process illustrated in FIG. 3B. Alternatively, the staircase shape of the stacked body LMsb may be formed by a method of collectively processing a staircase shape corresponding to a plurality of layers. In addition, at this time, the staircase shape may be a multi-row staircase.

At this time, the uppermost step of the staircase portion formed in the stacked body LMsa and the lowermost step of the staircase portion formed in the stacked body LMsb are brought close to each other such that the steps are continuously connected from the lower layer side of the stacked body LMsa to the upper layer side of the stacked body LMsb.

As illustrated in FIG. 4C, terrace portions of the plurality of sacrificial layers NL processed in the staircase shape in the stacked body LMsb are processed by, for example, RIE as in the process on the stacked body LMsa in FIG. 3C to reduce the layer thickness of the sacrificial layer NL of each terrace portion. At this time, it is preferable to process the terrace portion such that the layer thickness of the terrace portion is equal to or less than half of the original layer thickness of the sacrificial layer NL.

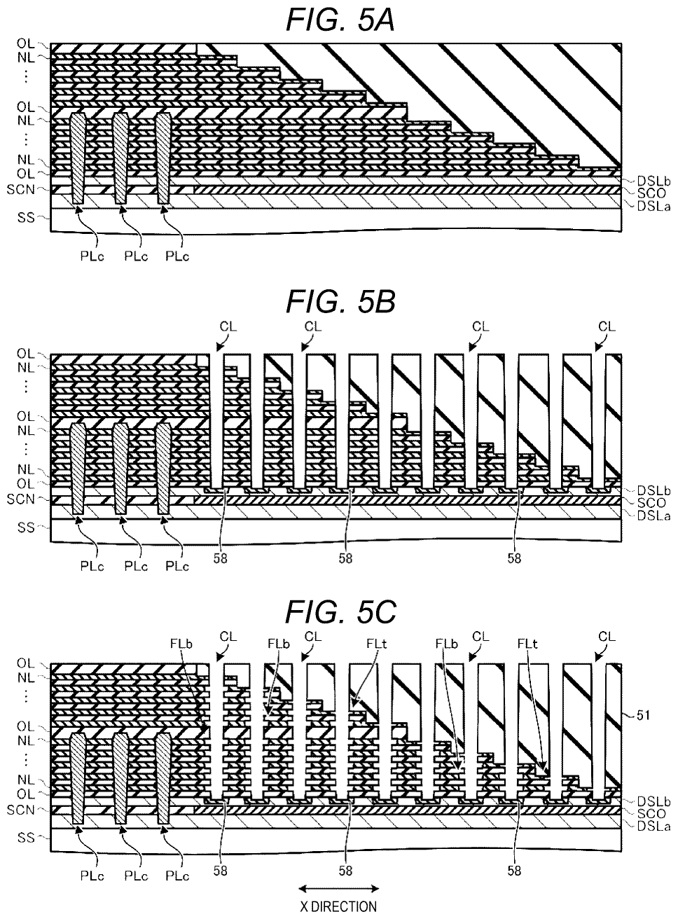

As illustrated in FIG. 5A, the insulating layer 51 that covers the upper surface of the insulating layer 51 covering the staircase shape of the stacked body LMsa and the staircase portion newly formed in the stacked body LMsb and reaches the height of the upper surface of the stacked body LMsb is formed. The insulating layer 51 is also formed in the outer region of the stacked bodies LMsa and LMsb.

As illustrated in FIG. 5B, a plurality of contact holes CL that extend through the insulating layer 51, the insulating layers NL constituting the terrace portions, and the layers below the insulating layers NL in the stacked bodies LMsa and LMsb and reach, for example, the upper source line DSLb are formed at positions that overlap each of the terrace portions of the insulating layers NL processed in the staircase shape in the stacked bodies LMsa and LMsb in the stacking direction.

In addition, a thermal oxidation treatment is performed on the upper source line DSLb, such as a polysilicon layer, exposed through the plurality of contact holes CL. Therefore, the exposed surface of the upper source line DSLb in lower end portions of the plurality of contact holes CL is oxidized, and an insulating layer 58, such as a silicon oxide layer, covering the lower end portions of the contact holes CL is formed.

As illustrated in FIG. 5C, the plurality of insulating layers NL exposed through the contact hole CL are retreated from the side wall of the contact hole CL by wet etching, chemical dry etching (CDE), or the like.

Therefore, flange portions FLt and FLb that protrude toward the plurality of insulating layers NL are formed on the side wall of the contact hole CL. The flange portion FLt is formed at the height position of the insulating layer NL, which constitutes each terrace portion, among the plurality of insulating layers NL through which the contact hole CL penetrates, and the flange portion FLb is formed at the height position of each of the insulating layers NL other than the insulating layer NL constituting the terrace portion.

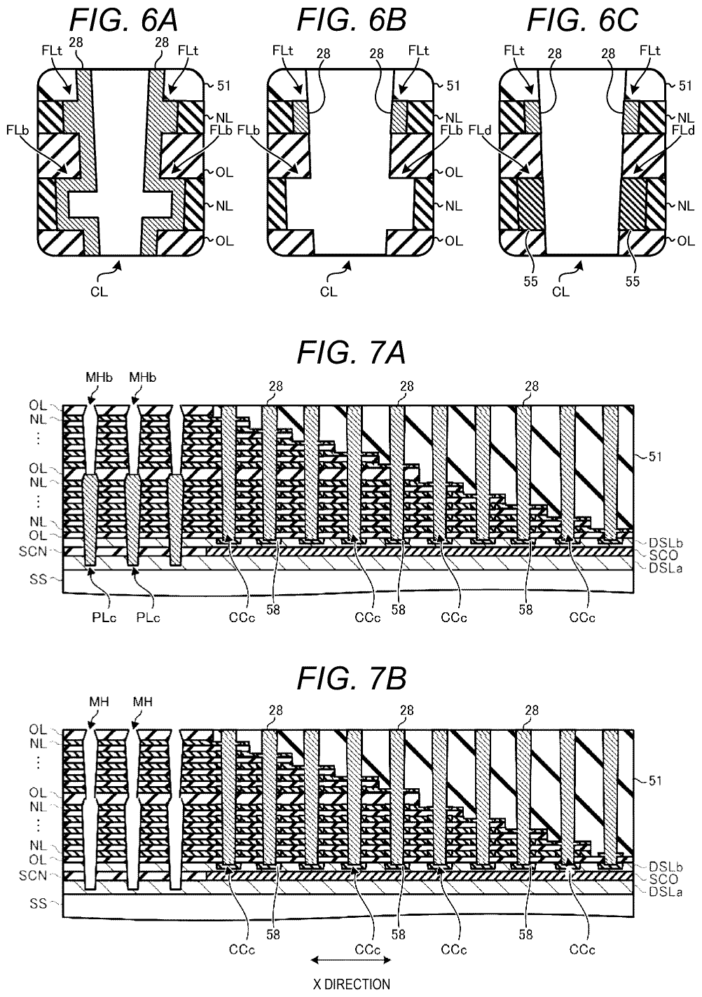

Then, the flange portion FLt is filled with a sacrificial layer 28, such as an amorphous silicon layer, and the flange portion FLb is filled with the insulating layer 55, such as a silicon oxide layer. This aspect is illustrated in FIGS. 6A to 6C. FIGS. 6A to 6C are enlarged cross-sectional views illustrating the contact hole CL penetrating the terrace portion of any insulating layer NL and illustrates a cross section corresponding to FIG. 2D.

As illustrated in FIG. 6A, the flange portions FLt and FLb are formed on the side wall of the contact hole CL by a wet etching process or the like on the contact hole CL.

At this time, the flange portion FLt is formed by a wet etching solution or an etchant for CDE eroding the terrace portion, which is thinner than the original insulating layer NL, toward the outside of the contact hole CL. Therefore, a retreat distance of the terrace portion, that is, a protrusion distance of the flange portion FLt is smaller than a retreat distance of the insulating layer NL below the insulating layer NL constituting the terrace portion, that is, a protrusion distance of the flange portion FLb.

As described above, the sacrificial layer 28 is formed on the side wall of the contact hole CL in which the flange portions FLt and FLb are formed. The sacrificial layer 28 may be an amorphous silicon layer or the like, may be a metal layer, such as a tungsten layer, or may be a silicon nitride layer or the like.

At this time, the sacrificial layer 28 is formed with a layer thickness where a void in the flange portion FLt is almost completely filled with the sacrificial layer 28 and a void in the flange portion FLb is not completely filled with the sacrificial layer 28. Therefore, the thin sacrificial layer 28 is formed on the side wall of the contact hole CL, the upper and lower surfaces of the flange portion FLb, and an end surface facing the insulating layer NL, and the flange portion FLt is almost completely filled with the sacrificial layer 28.

As illustrated in FIG. 6B, the sacrificial layer 28 formed on the side wall of the contact hole CL is removed by wet etching, CDE, or the like. At this time, the thin sacrificial layer 28 formed in the flange portion FLb is also removed. On the other hand, the flange portion FLt is almost completely filled with the sacrificial layer 28, and the aspect ratio of the flange portion FLt is lower than the aspect ratio of the flange portion FLb. Therefore, the sacrificial layer 28 filling the flange portion FLt is capable of being left almost intact without being removed.

In addition, after the sacrificial layer 28 is removed from the flange portion FLb, the end surface of the insulating layer NL exposed from the flange portion FLb may be further retreated by wet etching, CDE, or the like. In this case, since the flange portion FLt is filled with the sacrificial layer 28, the end surface of the sacrificial layer NL facing the flange portion FLt is not retreated. Therefore, the protrusion distance of the flange portion FLb is much larger than the protrusion distance of the flange portion FLt.

Then, the insulating layer 55, such as a silicon oxide layer, is formed again on the side wall of the contact hole CL. At this time, the layer thickness of the insulating layer 55 is adjusted such that the flange portion FLb is almost completely filled with the insulating layer 55. On the other hand, since the sacrificial layer 28 is already formed in the flange portion FLt, the insulating layer 55 is not formed in the flange portion FLt.

As illustrated in FIG. 6C, the insulating layer 55 formed on the side wall of the contact hole CL is removed by wet etching, CDE, or the like. At this time, the insulating layer 55 filling the flange portion FLb is left as it is.

As described above, the flange portion FLt filled with the sacrificial layer 28 and the flange portion FLd filled with the insulating layer 55 are formed on the side wall of the contact hole CL.

As illustrated in FIG. 7A, the entire contact hole CL is filled with the sacrificial layer 28, such as an amorphous silicon layer, again to form a contact CCc. In addition, even in this case, the sacrificial layer 28 may be a metal layer, such as a tungsten layer, in addition to the amorphous silicon layer.

Further, a plurality of memory holes MHb that extend through the stacked body LMsb in the stacking direction are formed. The memory hole MHb is a portion that will be an upper structure of the pillar PL later. The plurality of memory holes MHb are disposed in a region that will be the memory region MR later, penetrate the stacked body LMsb, and reach the upper end portions of the pillars PLc formed in the stacked body LMsa.

As illustrated in FIG. 7B, the sacrificial layer 26 is removed from the pillar PLc at the bottom of the memory hole MHb. Therefore, the memory holes MHa are open at the bottoms of the plurality of memory hole MHb, and the plurality of memory holes MH that penetrate the stacked bodies LMsb and LMsa, the upper source line DSLb, and the intermediate sacrificial layer SCN and reach the lower source line DSLa are formed.

Further, in a case where the sacrificial layer 26 filling the pillar PLc is a CVD-carbon layer or the like, the sacrificial layer 26 is capable of being collectively removed from the pillar PLC when the mask pattern and the like used in the process illustrated in FIG. 7A are removed by ashing using oxygen plasma or the like.

In addition, the processes illustrated in FIGS. 4A to 7B is interchangeable in order. As an example, the formation of the memory holes MH illustrated in FIGS. 7A and 7B may be performed before the formation of the staircase shape in the stacked body LMsb illustrated in FIGS. 4B and 4C or may be performed before the formation of the contacts CCc illustrated in FIGS. 5B to 6C.

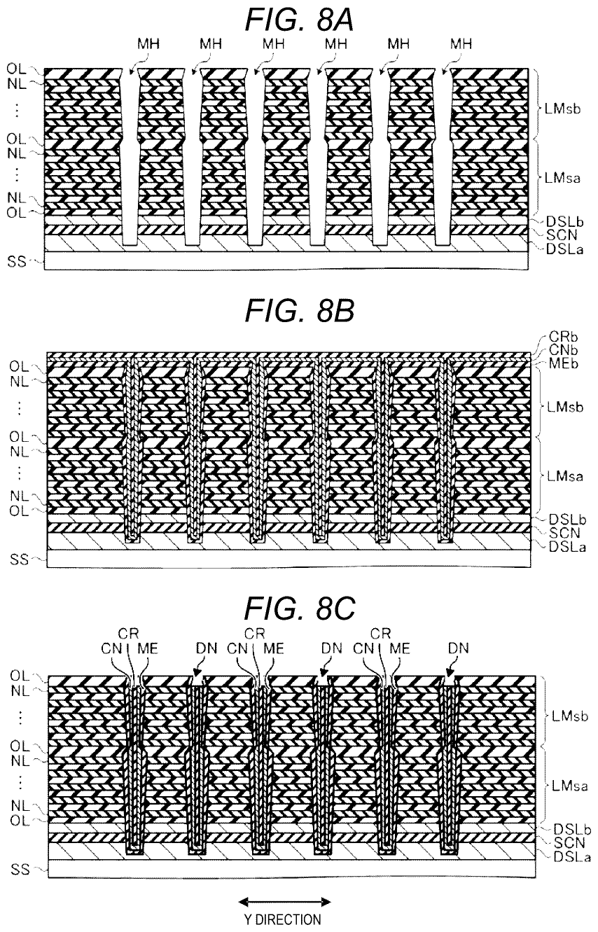

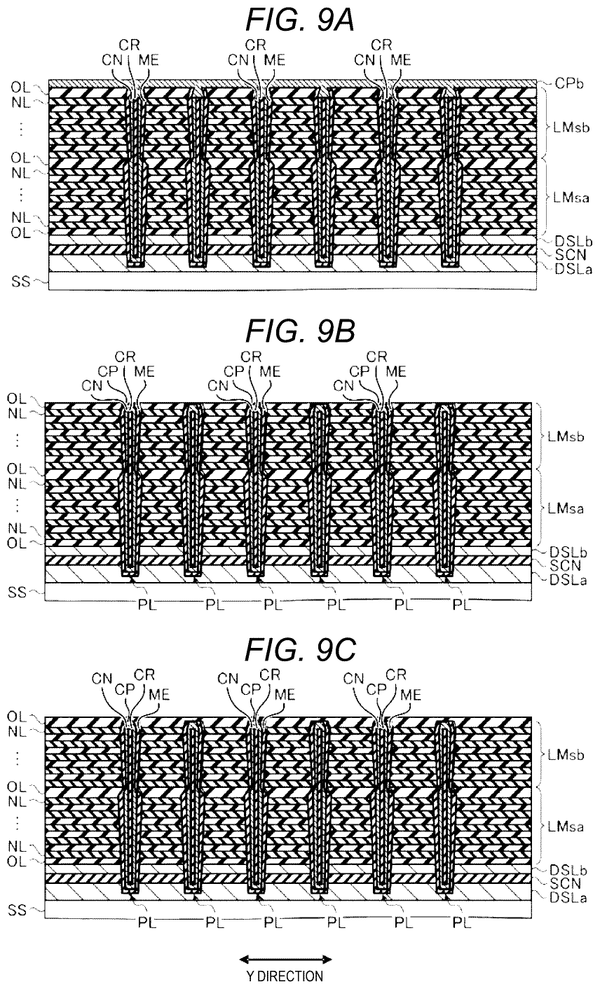

Next, an aspect in which a multilayer structure is formed in the memory hole MH to form the pillar PL will be described with reference to FIGS. 8A to 9C. FIGS. 8A to 9C are cross-sectional views illustrating the region that will be the memory region MR later taken along the Y direction.

As illustrated in FIG. 8A, a plurality of memory holes MH are formed in the region that will be the memory region MR later.

As illustrated in FIG. 8B, a multilayer insulating layer MEb, a semiconductor layer CNb, and an insulating layer CRb are formed in this order in the memory hole MH. Therefore, the multilayer insulating layer MEb and the semiconductor layer CNb are disposed on the side surface of the memory hole MH and on the bottom surface thereof from which the lower source line DSLa is exposed, and a central portion of the memory hole MH is filled with the insulating layer CRb.

The multilayer insulating layer MEb is an insulating layer having a multilayer structure that will be the memory layer ME later. The semiconductor layer CNb is a layer that will be the channel layer CN later. The insulating layer CRb is a silicon oxide layer or the like that will be the core layer CR later. The multilayer insulating layer MEb, the semiconductor layer CNb, and the insulating layer CRb are also formed in this order on the upper surface of the stacked body LMsb.

As illustrated in FIG. 8C, the insulating layer CRb, the semiconductor layer CNb, and the multilayer insulating layer MEb are sequentially etched back to be removed from the upper surface of the stacked body LMsb, and a depression DN obtained by removing the insulating layer CRb and the semiconductor layer CNb is formed in the upper end portion of the memory hole MH.

Therefore, the memory layer ME, the channel layer CN, and the core layer CR are formed in the memory hole MH in order from the outer peripheral side.

As illustrated in FIG. 9A, a semiconductor layer CPb is formed in the depression DN in the upper end portion of the memory hole MH. The semiconductor layer CPb is a layer that will be the cap layer CP later. The semiconductor layer CPb is also formed on the upper surface of the stacked body LMsb.

As illustrated in FIG. 9B, the semiconductor layer CPb on the upper surface of the stacked body LMsb is removed by chemical mechanical polishing (CMP) or the like, and the cap layer CP is formed in the upper end portion of the memory hole MH. In addition, the uppermost insulating layer OL of the stacked body LMsb, which is thinned by CMP or the like, is stacked.

Therefore, the pillar PL in which the cap layer CP is buried in the uppermost insulating layer OL is formed. However, at this time, the memory layer ME covers the entire side wall of the pillar PL, and a portion of the side surface of the channel layer CN is not exposed from the memory layer ME.

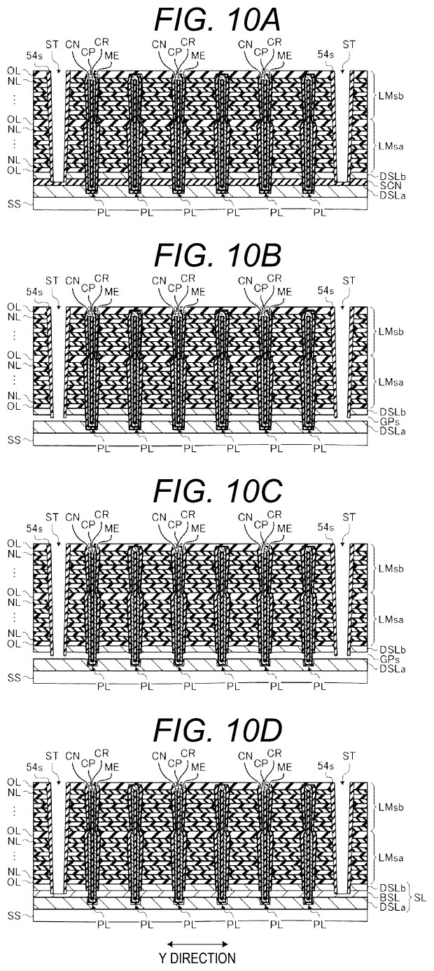

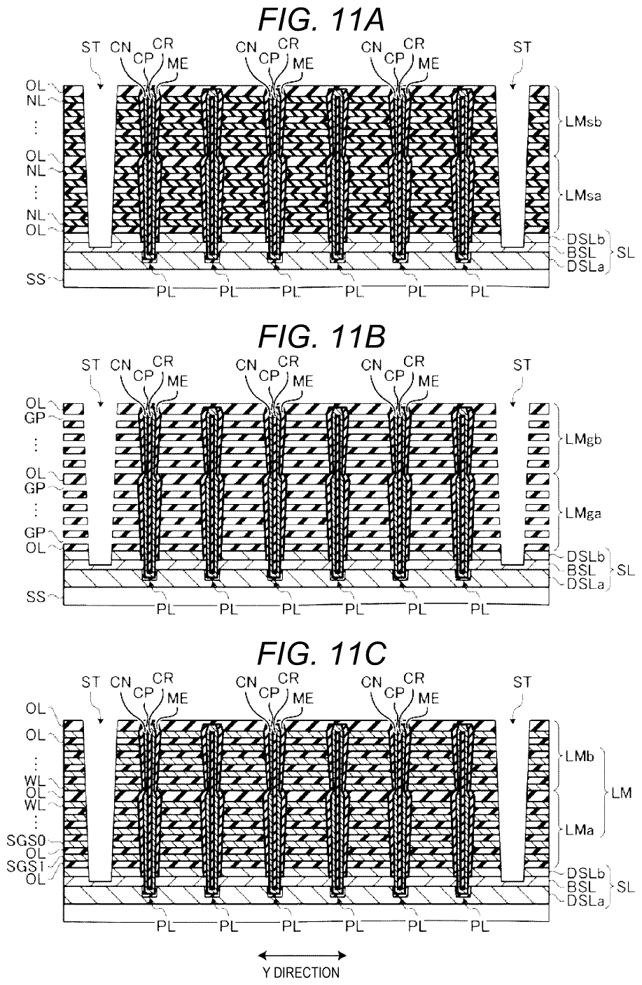

Next, an aspect in which the source line SL and the word line WL are formed will be described with reference to FIGS. 10A to 11C. FIGS. 10A to 11C are cross-sectional views illustrating the region that will be the memory region MR later taken along the Y direction, as in FIGS. 8A to 9C.

As illustrated in FIG. 10A, a slit ST that penetrates the stacked bodies LMsb and LMsa and the upper source line DSLb and reaches the intermediate sacrificial layer SCN is formed. In addition, an insulating layer 54s is formed on a side wall of the slit ST that faces the Y direction.

The slit ST has a tapered or bowed cross section in the Y direction and also extends in the direction along the X direction in the stacked bodies LMsa and LMsb. Therefore, in the staircase region SR (not illustrated), a lower end portion of the slit ST reaches the intermediate insulating layer SCO.

As illustrated in FIG. 10B, for example, a removal liquid for the intermediate sacrificial layer SCN, such as hot phosphoric acid, is allowed to flow into the slit ST whose side wall is protected by the insulating layer 54s to remove the intermediate sacrificial layer SCN interposed between the lower source line DSLa and the upper source line DSLb.

Therefore, a gap layer GPs is formed between the lower source line DSLa and the upper source line DSLb. In addition, a portion of the memory layer ME of the outer peripheral portion of the pillar PL is exposed in the gap layer GPs.

At this time, since the side wall of the slit ST is protected by the insulating layer 54s, the insulating layers NL in the stacked bodies LMsa and LMsb are prevented from being removed. In addition, in the staircase region SR (not illustrated), the intermediate sacrificial layer SCN is not provided between the lower source line DSLa and the upper source line DSLb, and the gap layer GPs is not formed.

As illustrated in FIG. 10C, a chemical solution is appropriately allowed to flow into the gap layer GPs through the slit ST to subsequently remove the block insulating layer BK, the charge storage layer CT, and the tunnel insulating layer TN (see FIGS. 2B and 2C) of the memory layer ME exposed in the gap layer GPs. Therefore, the memory layer ME is removed from a portion of the side wall of the pillar PL, and a portion of the inner channel layer CN is exposed in the gap layer GPs.

As illustrated in FIG. 10D, a raw material gas, such as amorphous silicon, is injected from the slit ST whose side wall is protected by the insulating layer 54s such that the gap layer GPs is filled with the amorphous silicon or the like. In addition, a heating treatment is performed on the supporting substrate SS to polycrystallize the amorphous silicon filling the gap layer GPs, thereby forming the intermediate source line BSL containing polysilicon or the like.

Therefore, a portion of the channel layer CN of the pillar PL is connected to the source line SL at the side through the intermediate source line BSL.

At this time, in the staircase region SR (not illustrated), the gap layer GPs is not formed between the lower source line DSLa and the upper source line DSLb. In addition, the intermediate source line BSL is not formed.

As illustrated in FIG. 11A, the insulating layer 54s on the side wall of the slit ST is once removed.

As illustrated in FIG. 11B, for example, a removal liquid for the insulating layer NL, such as hot phosphoric acid, is allowed to flow into the stacked bodies LMsa and LMsb from the slit ST to remove the insulating layers NL of the stacked bodies LMsa and LMsb. Therefore, stacked bodies LMga and LMgb having a plurality of gap layers GP obtained by removing the insulating layers NL between the insulating layers OL are formed.

The stacked bodies LMga and LMgb including the plurality of gap layers GP have a fragile structure. In the region that will be the memory region MR later, the plurality of pillars PL support the fragile stacked bodies LMga and LMgb. Therefore, the remaining insulating layers OL are prevented from being bent, and the stacked bodies LMga and LMgb are prevented from being distorted or collapsed.

As illustrated in FIG. 11C, a raw material gas of a conductive material, such as tungsten or molybdenum, is injected into the stacked bodies LMga and LMgb from the slit ST to fill the gap layers GP of the stacked bodies LMga and LMgb with the conductive material, thereby forming a plurality of word lines WL or the like. Therefore, the stacked body LM including the stacked bodies LMa and LMb in which the plurality of word lines WL or the like and the plurality of insulating layers OL are alternately stacked one by one is formed.

As described above, the process of forming the intermediate source line BSL from the intermediate sacrificial layer SCN and the process of forming the word line WL from the insulating layer NL are also referred to as a replacement process.

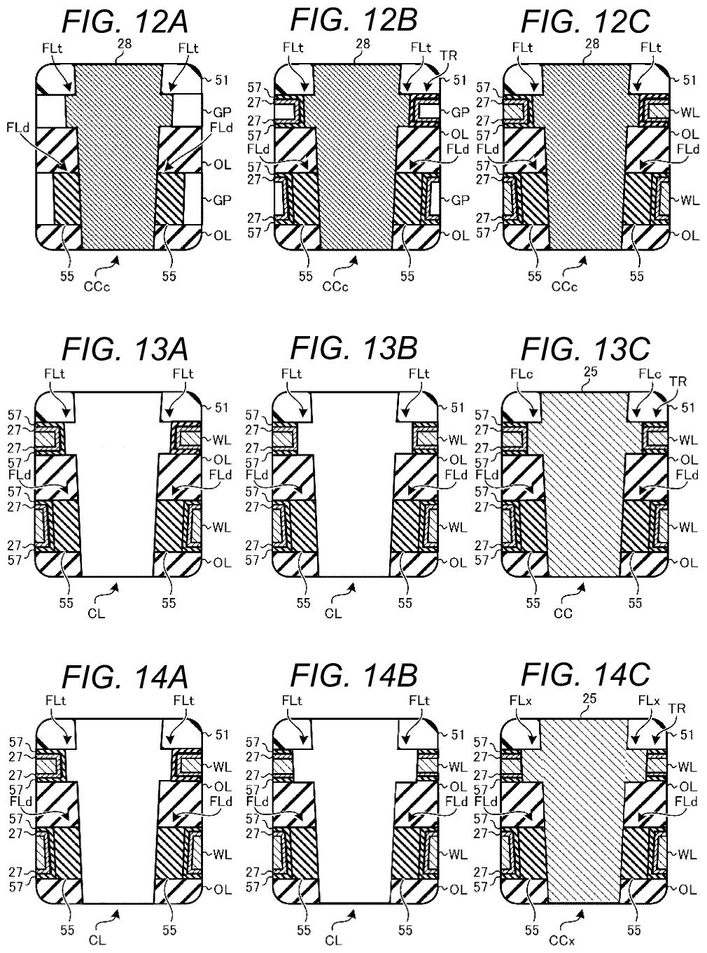

In addition, when the plurality of word lines WL or the like are formed, as described above, the metal-containing layer 27 and the metal-containing layer 57 are formed in this order in the plurality of gap layers GP, and then the plurality of gap layers GP are filled with the conductive material, such as tungsten, to form the word lines WL. A detailed formation procedure of the plurality of word lines WL or the like is illustrated in FIGS. 12A to 13C.

FIGS. 12A to 13C are enlarged cross-sectional views illustrating the contact hole CL penetrating the terrace portion of any insulating layer NL and illustrate a cross section corresponding to the cross section illustrated in FIGS. 6A to 6C.

As illustrated in FIG. 12A, the insulating layers NL are removed from the stacked bodies LMsa and LMsb, and a plurality of gap layers GP are formed by the process illustrated in FIG. 11B.

In addition, in the contact CCc, the main body portion and the flange portion FLt of the contact hole CL are filled with the sacrificial layer 28, and the insulating layer 55 is formed in the flange portion FLb by the process illustrated in FIGS. 6A to 7A.

However, as described above, when the flange portion FLt of the contact CCc is filled with a sacrificial layer, such as a silicon nitride layer, instead of the sacrificial layer 28 which is an amorphous silicon layer or the like, the sacrificial layer in the flange portion FLt is also removed by the process illustrated in FIG. 11B, and the gap layer GP at the height position of the flange portion FLt communicates with the flange portion FLt.

In addition, the insulating layers NL are removed from the stacked bodies LMsa and LMsb, and the plurality of gap layers GP are formed by the process illustrated in FIG. 11B.

As illustrated in FIG. 12B, the metal-containing layer 57 and the metal-containing layer 27 are formed in this order on both surfaces of the insulating layer OL exposed in the gap layer GP in the stacking direction and on the end surfaces of the flange portions FLt and FLd.

As illustrated in FIG. 12C, the gap layer GP in which the metal-containing layers 57 and 27 are formed is filled with a conductive material to form the word line WL or the like.

As illustrated in FIG. 13A, the sacrificial layer 28 filling the contact hole CL and the flange portion FLt is removed. Therefore, the metal-containing layer 57 is exposed to the end surface of the flange portion FLt facing the word line WL.

As illustrated in FIG. 13B, the metal-containing layer 57 exposed to the end surface of the flange portion FLt is removed. Therefore, the metal-containing layer 27 is exposed to the end surface of the flange portion FLt. However, at this time, the metal-containing layer 27 may be removed following the metal-containing layer 57. In this case, the end surface of the word line WL is exposed to the end surface of the flange portion FLt.

In addition, when the flange portion FLt is filled with a sacrificial layer, such as a silicon nitride layer, by the process illustrated in FIGS. 6A to 7A and the sacrificial layer is removed by the process illustrated in FIG. 11B, the metal-containing layers 57 and 27 are formed not on the end surface of the flange portion FLt, but on the side wall of the main body portion of the contact CCc at the height position of the flange portion FLt. Therefore, in the process illustrated in FIG. 13B, the metal-containing layer 57 or the like is removed from the side wall of the contact CCc.

As illustrated in FIG. 13C, the contact hole CL and the flange portion FLt are filled with the conductive layer 25. Therefore, the contact CC having the flange portion FLc filled with the conductive layer 25 and the flange portion FLd filled with the insulating layer 55 on the side wall thereof is formed.

At this time, the conductive layer 25 in the flange portion FLc and the word line WL constituting the terrace portion TR are in contact with each other directly or through the conductive metal-containing layer 27. Therefore, the contact CC is electrically connected to the word line WL constituting the terrace portion TR.

On the other hand, the insulating layer 55 and the insulating metal-containing layer 57 are interposed between the flange portion FLd and the word line WL or the like and the metal-containing layer 27 below the word line WL constituting the terrace portion TR. Therefore, the contact CC is prevented from being electrically connected to the word line WL or the like below the word line WL constituting the terrace portion TR.

In addition, for the sake of clarity, FIGS. 14A to 14C illustrate an example in which, in the process illustrated in FIG. 13B, both the metal-containing layers 57 and 27 are removed and a contact CCx in which the metal-containing layer 27 is not interposed between a flange portion FLx and the word line WL is formed.

FIGS. 14A to 14C correspond to FIGS. 13A to 13C, respectively. In the process illustrated in FIG. 14B, both the metal-containing layers 57 and 27 are removed, and the contact CCx in which the conductive layer 25 filling the flange portion FLx and the end surface of the word line WL at the height position of the flange portion FLx are directly connected to each other is formed.

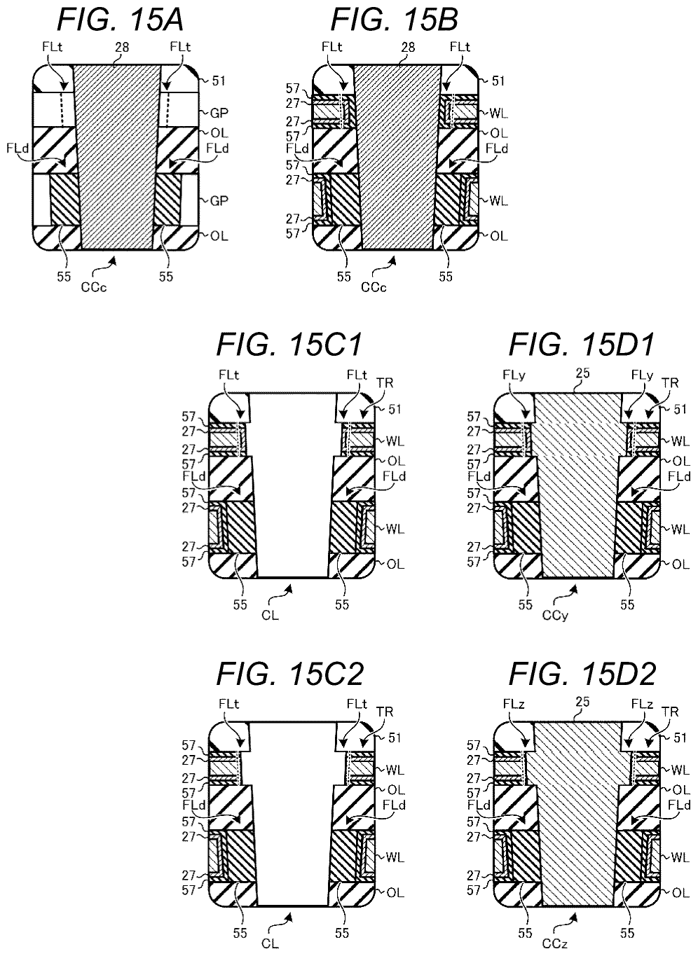

In addition, FIGS. 15A to 15D2 illustrate an example of a case where the metal-containing layer 27 is left in the process illustrated in FIG. 13B and an example of a case where the metal-containing layer 27 is removed when the flange portion FLt is filled with the sacrificial layer, such as a silicon nitride layer, in the process illustrated in FIGS. 6A to 7A.

As illustrated in FIG. 15A corresponding to FIG. 12A, a plurality of gap layers GP are formed in the stacked bodies LMga and LMgb, and the sacrificial layer, such as the silicon nitride layer, is removed from the flange portion FLt of the contact CCc by the process illustrated in FIG. 11B.

As illustrated in FIG. 15B corresponding to FIG. 12C, when the metal-containing layers 57 and 27 and the word line WL are formed in this order in the gap layer GP, the metal-containing layers 57 and 27 are also formed on the side wall of the contact CCc exposed in the flange portion FLt at the height position of the flange portion FLt.

As illustrated in FIG. 15C1 corresponding to FIG. 13B, the sacrificial layer 28 filling the contact CCc is removed, and the metal-containing layer 57 exposed in the contact hole CL is removed.

As illustrated in FIG. 15D1 corresponding to FIG. 13C, the contact hole CL is filled with the conductive layer 25 to form a contact CCy having flange portions FLY and FLd on a side wall thereof.

Meanwhile, as illustrated in FIG. 15C2 corresponding to FIG. 14B, the sacrificial layer 28 filling the contact CCc is removed, and both the metal-containing layers 57 and 27 exposed in the contact hole CL are removed.

As illustrated in FIG. 15D2 corresponding to FIG. 14C, the contact hole CL is filled with the conductive layer 25 to form a contact CCz having flange portions FLz and FLd on a side wall thereof.

As described above, in the process illustrated in FIGS. 6A to 7A, the flange portion FLt is filled with the sacrificial layer, such as a silicon nitride layer, which makes it possible to further extend the metal-containing layer 57, which covers the word line WL connected to the contact CCy or CCz, to the vicinity of the main body portion of the contact CC.

Then, the insulating layer 54 is formed on the side wall of the slit ST, and the insulating layer 54 is filled with the conductive layer 24 to form the plate-shaped contact LI. However, the slit ST may be filled with the insulating layer 54 or the like, without forming the conductive layer 24, to form a plate-shaped member.

In addition, a groove that penetrates one or a plurality of conductive layers including the uppermost conductive layer of the stacked body LMb is formed. Then, the groove is filled with the insulating layer 56 to form the separation layer SHE that partitions these conductive layers into the patterns of the select gate lines SGD.

Further, the insulating layer 52 is formed on the upper surface of the insulating layer 51 covering the upper surface of the stacked body LM and the staircase region SR, and the plug V0 that penetrates the insulating layer 52 and is connected to the contact CC is formed. In addition, the plug CH that penetrates the insulating layer 52 and is connected to the pillar PL is formed. Further, the insulating layer 53 is formed on the insulating layer 52 to form the upper layer wiring lines MX, the bit lines BL, and the like connected to the plugs V0 and CH. In addition, an electrode pad or the like for electrical connection with the peripheral circuit CBA is formed on the upper surface of the insulating layer 53.

Further, for example, the plugs V0 and CH, the upper layer wiring lines MX, the bit lines BL, and the like may be collectively formed by using a dual damascene method or the like.

In addition, the peripheral circuit CBA is formed on a semiconductor substrate SB separate from the supporting substrate SS on which the stacked body LM is formed and is covered with the insulating layer 40. A contact, a via, a wiring line, and the like for drawing out the peripheral circuit CBA to the surface of the insulating layer 40 are formed in the insulating layer 40 and are connected to the electrode pad and the like formed on the upper surface of the insulating layer 40.

Then, the supporting substrate SS and the semiconductor substrate SB are bonded to each other by the insulating layers 50 and 40 provided in the supporting substrate SS and the semiconductor substrate SB, respectively, to connect the electrode pads in the insulating layers 50 and 40. Then, the supporting substrate SS is removed to expose the source line SL, and the electrode film EL is connected through the insulating layer 60 in which the plugs PG are formed.

In this way, the semiconductor memory device 1 according to the embodiment is manufactured.

### Overview

A semiconductor memory device, such as a three-dimensional non-volatile memory, is configured such that a voltage is applicable to a plurality of word lines and the like by stacking the plurality of word lines and the like, forming some of the word lines and the like in a staircase shape, and connecting contacts to the staircase portions. These contacts are obtained, for example, by collectively forming a plurality of contact holes that penetrate the insulating layer covering the staircase portion and reach the terrace portions of the plurality of word lines and the like.

However, since the height difference between a plurality of word lines belonging to different layers of the stacked body is large, the contact hole that is to reach the word line and like on the upper layer side among the plurality of contact holes may penetrate the word line that the contact hole is to reach. In this case, when the contact hole reaches the word line in the lower layer, there is a concern that the word lines will be electrically connected to each other through the contact to be formed later.

Therefore, for example, a method may be adopted that thickens the terrace portions of the plurality of word lines and the like to reduce the penetration of the contact. In this case, a silicon nitride layer or the like that is made of the same material as the sacrificial layer is further stacked on the terrace portion of the sacrificial layer before the sacrificial layer is replaced with the word line to thicken the terrace portion.

In addition, there are some attempts to form the contact hole to penetrate the thickened sacrificial layer and the stacked body in the layer below the sacrificial layer and to connect the thickened word line and the contact after the sacrificial layer is replaced with the word line.

In this case, after the contact hole is formed, the sacrificial layer exposed in the contact hole is retreated by wet etching or the like, and then the retreated portion is filled with the insulating layer. At this time, since the void of the retreated portion formed in the thickened sacrificial layer is larger than the voids of the other sacrificial layers, the void remains without being filled with the insulating layer. When a conductive material is embedded in the contact hole to form the contact, the void formed in the thickened sacrificial layer is also filled with the conductive layer, which makes it possible to obtain the contact that is connected only to the thickened word line after the sacrificial layer is replaced with the word line.

However, the above-described method of thickening the terrace portion of the word line has various problems. For example, it is necessary to perform a process of separating a thick film portion of the terrace portion from a step surface of an upper step portion such that the thickened terrace portion does not come into contact with an end surface of the word line constituting the upper step portion of the terrace portion. When the separation process is insufficient, the word lines in the upper and lower layers are electrically connected to each other, and a short circuit occurs. On the other hand, when the separation process is excessively performed, the sacrificial layer constituting the terrace portion is broken.

According to the semiconductor memory device 1 of the embodiment, in the terrace portion TR, each of the plurality of word lines WL has a smaller layer thickness than each of the plurality of word lines WL in the region in which the pillars PL are disposed, and a predetermined word line WL through which the contact CC penetrates is electrically connected to the contact CC in the terrace portion TR. Since a connection portion between the contact CC and the word line WL is configured in this way, it is possible to easily form the contact CC that is connected to each of the plurality of word lines WL having a height difference therebetween.

According to the semiconductor memory device 1 of the embodiment, in each of the word lines WL in the layers below the word line WL to which the contact CC is to be connected, the end surface facing the contact CC is covered with the metal-containing layer 57, and the metal-containing layer 57 is not disposed on the end surface, which faces the contact CC, in the word line WL to which the contact CC is connected in the terrace portion TR.

Therefore, it is possible to electrically connect the contact CC and the word line WL to which the contact CC is to be connected in the terrace portion TR of the word line WL and to prevent the electrical connection between the contact CC and the word line WL in the layer below the word line WL to which the contact CC is to be connected.

According to the semiconductor memory device 1 of the embodiment, in the metal-containing layer 57 that covers both surfaces of the word line WL to which the contact CC is to be connected, the end portion facing the contact CC is located closer to the contact CC than the end portion facing the contact CC in the metal-containing layer 57 that covers both surfaces of each of the word lines WL in the lower layers.

Therefore, both the facing surfaces of the word lines WL adjacent to each other in the stacking direction are covered with the metal-containing layers 57, and the flange portion FLc of the contact CC faces the insulating layer 55 in the flange portion FLd in the lower layer, which makes it possible to reduce the leakage current between the word lines WL adjacent to each other in the stacking direction.

According to the semiconductor memory device 1 of the embodiment, the contact CC has the conductive flange portion FLc that protrudes from the side wall of the contact CC toward the word line WL to which the contact CC is to be connected and a plurality of insulating flange portions FLd that protrude from the side wall of the contact CC toward the lower word lines WL and are in contact with the metal-containing layers 57 covering the end surfaces of the lower word lines WL.

Therefore, it is possible to electrically connect the contact CC and the word line WL to which the contact CC is to be connected in the terrace portion TR of the word line WL and to prevent the electrical connection between the contact CC and the word line WL in the layer below the word line WL to which the contact CC is to be connected.

According to the semiconductor memory device 1 of the embodiment, the protrusion distance of the flange portion FLc is smaller than the protrusion distance of each of the plurality of flange portions FLd. Therefore, both the facing surfaces of the word lines WL adjacent to each other in the stacking direction are covered with the metal-containing layers 57, and the flange portion FLc of the contact CC faces the insulating layer 55 in the flange portion FLd in the lower layer, which makes it possible to reduce the leakage current between the word lines WL adjacent to each other in the stacking direction.

According to the semiconductor memory device 1 of the embodiment, the flange portion FLc is in contact with the end surface, which faces the contact CC, in the word line WL to which the contact CC is to be connected or is in contact with the metal-containing layer 27 covering the end surface, which faces the contact CC, in the word line WL to which the contact CC is to be connected. Therefore, in any of the above-described cases, it is possible to electrically connect the contact CC and the word line WL to which the contact CC is to be connected in the terrace portion TR of the word line WL.

According to the method for manufacturing the semiconductor memory device 1 of the embodiment, the lower insulating layer NL is more retreated from the side wall of the contact hole CL than the insulating layer NL that will be the word line WL to which the contact is to be connected, using the difference in layer thickness between the insulating layer NL that will be the word line WL to which the contact is to be connected and the lower insulating layer NL.

Therefore, it is possible to obtain the above-described configuration in which both the facing surfaces of the word lines WL adjacent to each other in the stacking direction are covered with the metal-containing layer 57 and the flange portion FLc of the contact CC faces the insulating layer 55 in the flange portion FLd in the lower layer.

The method for manufacturing the semiconductor memory device 1 according to the embodiment includes forming the sacrificial layer 28 covering the side wall of the contact hole CL with a layer thickness where the flange portion FLt is filled with the sacrificial layer 28 and the plurality of flange portions FLb are not filled with the sacrificial layer 28. Therefore, in the subsequent process of forming the insulating layer 55, it is possible to fill only the flange portion FLb with the insulating layer 55.

According to the method for manufacturing the semiconductor memory device 1 of the embodiment, after the flange portion FLt is filled with the sacrificial layer 28, the insulating layers NL are further retreated from the end portions of the plurality of flange portions FLb. Therefore, it is possible to obtain the configuration in which the protrusion distance of the plurality of flange portions FLb is much larger than the protrusion distance of the flange portion FLt and, subsequently, the leakage current between the word lines WL adjacent to each other in the stacking direction is reduced.

According to the method for manufacturing the semiconductor memory device 1 of the embodiment, the metal-containing layer 57 exposed to the end surface of the flange portion FLt by the removal of the sacrificial layer 28 is removed. Therefore, it is possible to electrically connect the contact CC and the word line WL to which the contact CC is to be connected in the terrace portion TR of the word line WL.

### Other Modification Examples

In addition, in the above-described embodiment, in a method of drawing out a plurality of word lines WL and the like on one side, in the staircase region SR on one side in the X direction, the contacts are alternately disposed in the Y direction for every two block regions BLK. However, in the method of drawing out the word lines WL and the like on one side, the contacts may be disposed on one side in the X direction in the same block region BLK, and the disposition order is not limited to the above.

In addition, in the above-described embodiment, the staircase regions SR are provided on both sides of the stacked body LM in the X direction. However, the disposition of the staircase regions SR is not limited thereto. As an example, for example, the staircase region may be provided in the central portion of the stacked body in the X direction, and the memory regions may be provided on both sides in the X direction. In this case, the staircase region is capable of being disposed in the central portion of the stacked body by digging the central portion of the stacked body in a mortar bowl shape.

In addition, in the above-described embodiment, the stacked body LM with a two-tier structure is provided. However, the configuration of the stacked body may be one tier or may be three or more tiers.

Further, in the above-described embodiment, in the pillar PL, the side surface of the channel layer CN is connected to the source line SL. However, the present disclosure is not limited thereto. For example, the pillar may be connected such that the memory layer in the bottom surface of the pillar is removed and the lower end portion of the channel layer is connected to the source line.

In addition, in the above-described embodiment, the peripheral circuit CBA is disposed above the stacked body LM. However, the peripheral circuit may be disposed below the stacked body or in the same layer as the stacked body.

When the peripheral circuit is disposed below the stacked body, for example, the source line and the stacked body are capable of being formed on the insulating layer of the semiconductor substrate having the peripheral circuit covered with the insulating layer. When the peripheral circuit is disposed in the same layer as the stacked body, it is possible to form the stacked body at a position different from the position of the peripheral circuit on the semiconductor substrate on which the peripheral circuit is formed.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body in which a plurality of conductive layers and a plurality of insulating layers are alternately stacked, wherein the stacked body has a staircase portion in which a terrace portion of the plurality of conductive layers is processed in a staircase shape;
a pillar that penetrates the stacked body at a position away from the staircase portion in a first direction intersecting a stacking direction of the stacked body; and
a contact that penetrates the terrace portion of one conductive layer among the plurality of conductive layers and lower conductive layers below the one conductive layer in the staircase portion, the one conductive layer being electrically connected to the contact in the terrace portion,
wherein, in the terrace portion, each of the plurality of conductive layers has a layer thickness smaller than a layer thickness of each of the plurality of conductive layers in a region in which the pillar is disposed,
both surfaces of each of the plurality of conductive layers in the stacking direction including the terrace portion are covered with a first metal-containing layer,
in each of the lower conductive layers which the contact penetrates, an end surface facing the contact is covered with the first metal-containing layer.

2. The semiconductor memory device according to claim 1,
wherein the first metal-containing layer is a metal oxide layer and is not disposed on an end surface of the one conductive layer facing the contact.

3. The semiconductor memory device according to claim 1,
wherein the contact includes:
a conductive first flange portion that protrudes from a side wall of the contact toward the one conductive layer; and
a plurality of insulating second flange portions that protrude from the side wall of the contact toward the lower conductive layers and are in contact with the first metal-containing layers covering the end surfaces of the lower conductive layers.

4. The semiconductor memory device according to claim 3, wherein a layer thickness of the first flange portion is substantially equal to a layer thickness of the one conductive layer.

5. The semiconductor memory device according to claim 3, wherein a layer thickness of the plurality of insulating second flange portions is substantially equal to a layer thickness of the lower conductive layers.

6. The semiconductor memory device according to claim 3,
wherein a protrusion distance of the first flange portion from the side wall of the contact is smaller than a protrusion distance of each of the plurality of second flange portions from the side wall of the contact.

7. The semiconductor memory device according to claim 3,
wherein the first flange portion has the same material as a main body portion of the contact and is configured integrally with the main body portion of the contact.

8. The semiconductor memory device according to claim 3,
wherein the first flange portion does not have a portion overlapping, in a height direction, a conductive layer adjacent to the one conductive layer in the stacking direction.

9. The semiconductor memory device according to claim 1,
wherein the lower conductive layers are not electrically connected to the contact in the terrace portion.

10. The semiconductor memory device according to claim 1,
an end portion facing the contact in the first metal-containing layer that covers both surfaces of the one conductive layer, is located closer to the contact than an end portion facing the contact in the first metal-containing layer that covers both surfaces of each of the lower conductive layers.

11. A method for manufacturing a semiconductor memory device, the method comprising:
forming a stacked body in which a plurality of first sacrificial layers and a plurality of first insulating layers are alternately stacked;
processing a terrace portion of each of the plurality of first sacrificial layers in a staircase shape to form a staircase portion of the stacked body;
thinning the terrace portion of each of the plurality of first sacrificial layers;
forming a pillar that penetrates the stacked body at a position away from the staircase portion in a first direction intersecting a stacking direction of the stacked body;
forming a contact hole that penetrates the terrace portion of one first sacrificial layer among the plurality of first sacrificial layers and lower first sacrificial layers below the one first sacrificial layer in the staircase portion;
retreating the one first sacrificial layer and the lower first sacrificial layers, which are exposed to a side wall of the contact hole, from the side wall to form a first flange portion that protrudes toward the one first sacrificial layer on the side wall of the contact hole at a height position of the one first sacrificial layer and to form a plurality of second flange portions that protrude toward the lower first sacrificial layers on the side wall of the contact hole at height positions of the lower first sacrificial layers;
filling each of the plurality of second flange portions with a second insulating layer;
replacing each of the plurality of first sacrificial layers with a conductive material to form one first conductive layer from the one first sacrificial layer and to form lower first conductive layers from the lower first sacrificial layers; and
filling the contact hole and the first flange portion with a second conductive layer to form a contact connected to the one first conductive layer in the terrace portion of the one first conductive layer.

12. The method for manufacturing a semiconductor memory device according to claim 11,
wherein the retreating of the one first sacrificial layer and the lower first sacrificial layers includes:
more retreating the lower first sacrificial layers from the side wall of the contact hole than retreating the one first sacrificial layer, using a difference in layer thickness between the one first sacrificial layer and the lower first sacrificial layers.

13. The method for manufacturing a semiconductor memory device according to claim 11,
wherein the retreating of the one first sacrificial layer and the lower first sacrificial layers includes:
more retreating the lower first sacrificial layers from the side wall of the contact hole than retreating the one first sacrificial layer, so that a retreat distance of the one first sacrificial layer from the side wall is smaller than a retreat distance of the lower first sacrificial layers from the side wall.

14. The method for manufacturing a semiconductor memory device according to claim 11,
wherein the filling of the plurality of second flange portions with the second insulating layer includes:
filling the first flange portion with a second sacrificial layer.

15. The method for manufacturing a semiconductor memory device according to claim 14,
wherein the filling of the plurality of second flange portions with the second insulating layer further includes:
filling each of the plurality of second flange portions with the second insulating layer after filling the first flange portion with the second sacrificial layer.

16. The method for manufacturing a semiconductor memory device according to claim 14,
wherein the filling of the first flange portion with the second sacrificial layer includes:
forming the second sacrificial layer that covers the side wall of the contact hole with a layer thickness where the first flange portion is filled with the second sacrificial layer and the plurality of second flange portions are not filled with the second sacrificial layer.

17. The method for manufacturing a semiconductor memory device according to claim 16,
wherein the filling of the plurality of second flange portions with the second insulating layer includes:
further retreating the lower first sacrificial layers from end portions of the plurality of second flange portions after filling the first flange portion with the second sacrificial layer; and
filling each of the plurality of second flange portions with the second insulating layer after the lower first sacrificial layers are further retreated with the second insulating layer.

18. The method for manufacturing a semiconductor memory device according to claim 14,
wherein the filling of the plurality of second flange portions with the second insulating layer further includes:
forming the second sacrificial layer that covers the side wall of the contact hole; and
after the first flange portion is filled with the second sacrificial layer, removing the second sacrificial layer formed on the side wall of the contact hole.

19. The method for manufacturing a semiconductor memory device according to claim 18,
wherein the filling of the plurality of second flange portions with the second insulating layer further includes:
filling each of the plurality of second flange portions with the second insulating layer after removing the second sacrificial layer.

20. The method for manufacturing a semiconductor memory device according to claim 11,
wherein the processing the terrace portion of each of the plurality of first sacrificial layers in the staircase shape includes:
repeating slimming of a mask pattern of a photoresist layer and etching of the plurality of first sacrificial layers in the stacked body a plurality of times.
